(19) United States
(12) Patent Application Publication
(10) Pub. No.: US 2009/0214772 A1
(43) Pub. Date: Aug. 27, 2009

(54) METHOD AND APPARATUS FOR COATING POWDER MATERIAL ON SUBSTRATE

(75) Inventors: Sung Hoon Ahn, Seongnam-si (KR); Doo Man Chun, Seoul (KR); Min Hyeng Kim, Seoul (KR); Jae Chul Lee, Seoul (KR)

Correspondence Address: HARNESS, DICKEY, & PIERCE, P.L.C, 7700 Bonhomme, Suite 400, ST. LOUIS, MO, 63105, US

(73) Assignee: SEOUL NATIONAL UNIVERSITY INDUSTRY FOUNDATION, Seoul (KR)

(21) Appl. No.: 12/038,548

(22) Filed: Feb. 27, 2008

(51) Int. Cl. B05D 1/12; C23C 14/56

(52) U.S. Cl. 427/201; 427/180; 118/50

(57) ABSTRACT

An apparatus and method for coating a powder material on a substrate is disclosed, to enable various materials such as metal or ceramic powder to be coated on a substrate made of a material having low heat-resistance, the method including supplying a predetermined powder; carrying the supplied powder to a predetermined spraying nozzle by injecting a gas at a room temperature; and spraying the powder carried under conditions of the room temperature and vacuum state on the substrate through spraying nozzle, wherein the grain size of predetermined powder is in a range between about 0.1 to about 10 μm, and the powder is sprayed on the substrate at a velocity of about 500 to about 1200 m/sec.

### FIELD

The present invention generally relates to a method for coating various kinds of materials on a substrate, and more particularly to a method for coating various materials such as metal or ceramic on various substrates made of metal, ceramic or polymer under low temperature conditions.

### BACKGROUND

The statements in this section merely provide background information related to the present disclosure and may not constitute prior art.

There are many methods for coating a certain material on a substrate, for example, chemical vapor deposition (CVD), thermal spray, and gas deposition.

The chemical vapor deposition (CVD), which is generally used in a semiconductor-fabrication process, can perform deposition of a predetermined material on a surface of substrate through a chemical reaction between the surface of substrate heated and a vapor-type material. However, the chemical vapor deposition (CVD) may cause limitations on application of various materials such a metal material since the chemical vapor deposition (CVD) uses the vapor-type material. In addition, since the chemical vapor deposition (CVD) is performed under high temperature conditions, for example, 1000° C. or above, it is difficult to coat the predetermined material on a substrate made of polymer having low heat-resistance.

The thermal spray performs deposition of a predetermined material on a surface of substrate with steps of melting a powder material through the use of a thermal source, colliding rapidly the melted material with the surface of substrate, quenching and solidifying the melted material. Also, the gas deposition performs deposition of a predetermined material on a surface of substrate with steps of converting a metal or ceramic material into ultra-fine particles by evaporating a metal or ceramic material through the use of a thermal source of high temperature, and inducing a cohesion of the ultra-fine particles on the surface of substrate by spraying the ultra-fine particles on the surface of substrate through the use of gas of high temperature.

The thermal spray and gas deposition enable coating of the various kinds of materials such as metal or ceramic on the surface of substrate. However, the thermal spray and gas deposition may have a problem such as deformation of the substrate made of polymer having low heat-resistance by a thermal impact because each of the thermal spray and gas deposition is performed at a high temperature of 600° C. or above.

The related art chemical vapor deposition, thermal spray and gas deposition have limitations on application of various materials to be coated on the substrate having low heat-resistance. Thus, there have been attempts to coat the predetermined material on the substrate made of the various kinds of materials by performing a coating process at a low temperature. One example is a cold spraying method.

The cold spraying method performs deposition of a predetermined material on a surface of substrate with steps of supplying a powder material at a relatively low temperature of 300 to 600° C. and deforming powder particles by colliding the powder material with the surface of substrate through the use of supersonic at an atmospheric pressure.

Hereinafter, a related art cold spraying method will be described with reference to the accompanying drawings.

FIG. 1 is a diagram schematically illustrating a related art cold spraying apparatus. As shown in FIG. 1, the related art cold spraying apparatus is provided with a gas supplying unit 10, a powder supplying unit 20, a heating unit 30, a chamber 40, and a spraying nozzle 50.

As the gas supplying unit 10 supplies gas, some of the gas is supplied to the powder supplying unit 20 so as to carry a powder material, and the rest of the gas is supplied to the heating unit 30.

After the heated gas is mixed with the gas for carrying the powder material, powder particles of the mixed gas are sprayed through the spraying nozzle 50. The powder particles being sprayed collide with a surface of substrate 1 which is loaded in the chamber 40, and are embedded in the substrate 1, whereby the surface of substrate 1 is coated with the powder particles.

However, the related art cold spraying method has the following disadvantageous properties and limits of application.

First, the cold spraying method can perform the coating process of which the temperature is relatively lower than that of the chemical vapor deposition, thermal spray or gas deposition. However, since the cold spraying method requires the temperature of 300 to 600° C. in its coating process, it is difficult to coat the predetermined material on the substrate made of a material sensitive to heat through the use of cold spraying method. Especially, in case of a display device using a flexible substrate which has attracted great attentions as a next-generation display device, the process temperature of 300 to 600° C. required in the cold spraying method is too high for the flexible substrate formed of organic polymer having low heat-resistance. For the cold spraying method that requires the process temperature of 300 to 600° C., it is necessary to require the heating unit 30 and a complicated structure of pipe lines for carrying the gas therethrough, as shown in FIG. 1, thereby causing the cost increase.

Also, the substrate is coated with the powder particles by sequential steps for collision of the powder particles with the substrate and embedment of the powder particles in the substrate. In this case, if the diameter of powder particle is smaller than a predetermined value, it is not embedded in the substrate. Thus, there is a requirement for using the powder particle having the diameter above the predetermined value, thereby causing bad effects on the surface of substrate.

The cold spraying method can be applied only to the metal-powder coating process due to its process limitation. That is, if there is a need to coat the ceramic powder on the substrate, coating of the ceramic powder can be realized through the use of metal powder including the ceramic powder mixed therewith. Accordingly, it leads to limitation in selection of coating material.

### SUMMARY OF THE INVENTION

Accordingly, the present invention is generally directed to an apparatus and method for coating a powder material on a substrate that substantially obviates one or more problems due to limitations and disadvantages of the related art.

In an embodiment, the present invention provides an apparatus and method for coating a powder material on the substrate made of a material sensitive to heat, in which the powder material is coated on the substrate at a room temperature.

In another embodiment, the present invention provides an apparatus and method for coating a powder material on a substrate, to minimize bad effects on the substrate by using small-sized powder particles.

In yet another embodiment, the present invention provides an apparatus and method for coating a powder material on a substrate, to enable various materials such as metal or ceramic powder to be coated on the substrate.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of coating powder on a substrate includes supplying a predetermined powder; carrying the supplied powder to a predetermined spraying nozzle by injecting a gas at a room temperature; and spraying the powder carried under conditions of the room temperature and vacuum state on the substrate through spraying nozzle, wherein the grain size of predetermined powder is in a range between about 0.1 to about 10 μm, and the powder is sprayed on the substrate at a velocity of about 500 to about 1200 m/sec.

The present invention is achieved based on study results showing that a powder coating process can be performed at a room temperature by controlling conditions of a chamber for the coating process, a grain size of the powder, and a velocity of spraying the powder on a substrate, so that it enables the powder to be coated on a substrate made of an organic polymer having a low heat-resistance. In more detail, if the chamber for the coating process is maintained under a vacuum state instead of an atmospheric pressure, the grain size of powder is set in a range between about 0.1 and about 10 μm, and the powder is sprayed at a velocity of about 500 to about 1200 m/sec, the powder is smoothly coated on the substrate without the heating step for the powder.

The vacuum state maintained in the chamber for the coating process makes better environments for deposition by reducing drag in powder, whereby deceleration of the powder being prevented. Furthermore, according as the grain size of powder is relatively smaller, and the velocity of spraying the powder is relatively faster, the powder is smoothly deposited on the substrate through the collision of powder particles against the substrate.

The small-sized powder particles minimize the deformation of substrate during their collision against the substrate. If a ceramic powder prepared under the aforementioned conditions is sprayed on the substrate, ceramic powder particles are deformed and recombined by the collision against the substrate so that the ceramic powder particles are properly coated on the substrate. As a result, various kinds of powder materials, such as metal or ceramic powder, can be coated on the substrate.

In another aspect, a powder coating apparatus includes a chamber; a vacuum pump, coupled with the chamber, for making the chamber of a vacuum state; a substrate supporter, disposed inside the chamber, for supporting a predetermined substrate; a spraying nozzle, disposed inside the chamber, for spraying a predetermined powder on the substrate; a gas supplier, disposed outside the chamber, for supplying a predetermined gas; a pipe, having one end coupled with the gas supplier and the other end coupled with the spraying nozzle, for guiding the gas supplied from the gas supplier to the spraying nozzle; and a powder supplier, coupled with the pipe, for supplying the predetermined powder to the pipe through which the gas flows.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention without limiting the scope of the present disclosure.

FIG. 1 is a diagram schematically illustrating a related art cold spraying apparatus;

FIG. 2 is a diagram schematically illustrating a powder coating apparatus according to one embodiment of the present invention;

FIG. 3 is a diagram schematically illustrating a powder coating apparatus according to another embodiment of the present invention;

FIG. 4 is a diagram schematically illustrating a powder coating apparatus according to another embodiment of the present invention;

FIG. 5A shows optical images when TiO₂ powder is coated on a stainless steel substrate, FIG. 5B shows SEM images when TiO₂ powder is coated on a stainless steel substrate, and FIG. 5C shows EDX analysis graph when TiO₂ powder is coated on a stainless steel substrate;

FIG. 6A shows optical images when TiO₂ powder is coated on an aluminum alloy substrate, and FIG. 6B shows EDX analysis graph when TiO₂ powder is coated on an aluminum alloy substrate;

FIG. 7A shows optical images when TiO₂ powder is coated on a copper alloy substrate, and FIG. 7B shows EDX analysis graph when TiO₂ powder is coated on a copper alloy substrate;

FIG. 8A shows optical images when TiO₂ powder is coated on a PET substrate, and FIG. 8B shows XPS analysis graph when TiO₂ powder is coated on a PET substrate;

FIG. 9A shows optical images when TiO₂ powder is coated on a PMMA substrate, and FIG. 9B shows XPG analysis graph when TiO₂ powder is coated on a PMMA substrate;

FIG. 10A shows optical images when Sn powder is coated on a stainless steel substrate, and FIG. 10B shows XPS analysis graph when Sn powder is coated on a stainless steel substrate; and

FIG. 11A shows optical images in a comparative example, and FIG. 11B shows EDX analysis graph in a comparative example.

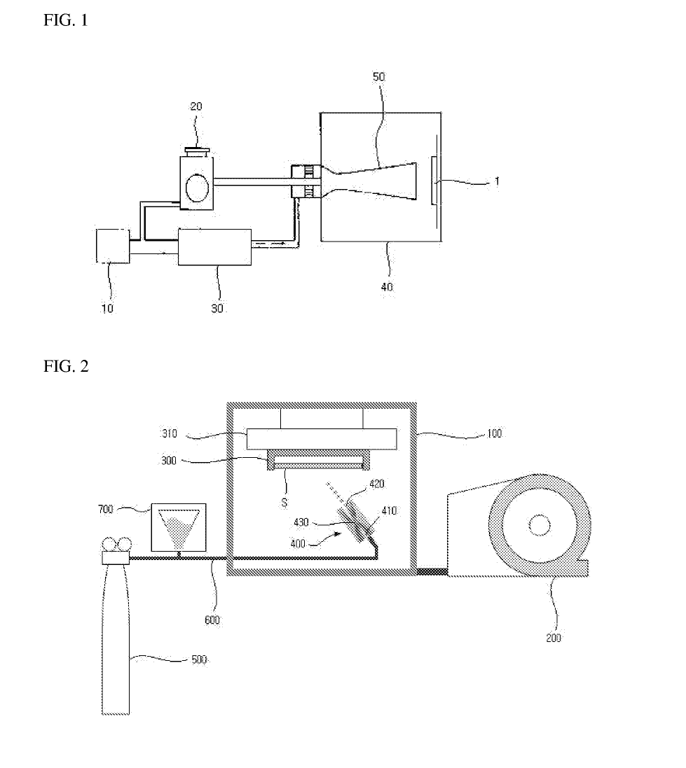

### DETAILED DESCRIPTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, an apparatus and method for coating a powder material on a substrate according to the present invention will be described with reference to the accompanying drawings.

FIG. 2 is a diagram schematically illustrating a powder coating apparatus according to one embodiment of the present invention. As shown in FIG. 2, the powder coating apparatus according to one embodiment of the present invention is provided with a chamber 100, a vacuum pump 200, a substrate supporter 300, a spraying nozzle 400, a gas supplier 500, a pipe 600, and a powder supplier 700.

The substrate supporter 300 and the spraying nozzle 400 are placed inside the chamber 100. As the vacuum pump 200 is coupled with the chamber 100, an operation of the vacuum pump 200 makes the chamber 100 of a vacuum state.

The substrate supporter 300 provided inside the chamber 100 supports a predetermined substrate (S), wherein the substrate supporter 300 is movable along the X-axis and Y-axis by a predetermined driver 310. According to the movement of substrate (S) along the X-axis and Y-axis, the substrate (S) fixed to the substrate supporter 300 is also moved along the X-axis and Y-axis. Thus, powder can be coated in a predetermined pattern on the substrate (S). In this case, the substrate (S) may be made of metal, ceramic or polymer.

The spraying nozzle 400 is provided inside the chamber 100. The spraying nozzle 400 sprays the powder on the substrate (S) so that the substrate (S) is coated with the powder. The spraying nozzle 400 includes a first opening 410, a second opening 420, and a nozzle throat 430. The first opening 410 is coupled with the pipe 600 so as to receive the powder supplied through the pipe 600, and the second opening 420 sprays the received powder on the substrate (S). The nozzle throat 430 is disposed between the first opening 410 and the second opening 420, wherein the nozzle throat 430 has a diameter of about 100 μm to about 3 mm. In this case, the diameter of nozzle throat 430 becomes gradually smaller in a direction from the first opening 410 toward the nozzle throat 430, whereas the diameter of nozzle throat 430 becomes gradually larger in a direction from the nozzle throat 430 toward the second opening 420. Through the spraying nozzle 400 having the aforementioned structure, the powder is sprayed at a velocity of about 500 to about 1200 m/sec, and more preferably, 600 to 1200 m/sec.

The spraying nozzle 400 is tilted with respect to the plane of substrate (S) so as to slantingly spray the powder on the plane of substrate (S). If the powder is sprayed perpendicular to the plane of substrate (S), gas molecules sprayed with the powder are reflected on the plane of substrate (S). The reflection of gas molecules may cause the change in spraying velocity of the powder, thereby resulting in poor quality of coating pattern, that is, undesired coating patterns. In order to maintain a constant spraying velocity of the powder, it is preferable that the powder be sprayed with respect to the plane of substrate (S) at a predetermined tilt angle. For this, preferably, the spraying nozzle 400 is tilted with respect to the plane of substrate (S). Alternatively, the substrate (S) may be tilted at a predetermined angle when the spraying nozzle 400 is perpendicular to a horizontal plane.

The gas supplier 500, provided outside the chamber 100, supplies the gas to carry the powder. A velocity of the powder sprayed through the spraying nozzle 400 can be controlled with the gas-injection pressure from the gas supplier 500 and the aforementioned structure of spraying nozzle 400. The gas supplier 500 may supply gas such as helium, nitrogen, oxygen or air.

One end of the pipe 600 is coupled with the gas supplier 500, and the other end of the pipe 600 is coupled with the spraying nozzle 400. Through the pipe 600, the gas is supplied from the gas supplier 500 to the spraying nozzle 400.

The powder supplier 700, coupled with the pipe 600, supplies the powder to the pipe 600. The powder supplied from the powder supplier 700 may be metal or ceramic powder, of which the grain size is about 0.1 to about 10 μm.

A heater (not shown) may be additionally provided between the spraying nozzle 400 and the powder supplier 700. The heater may heat the carried powder to a temperature range between a room temperature and about 300° C. When the powder is heated to the aforementioned temperature range by the heater, the spraying velocity of powder may be set in a range between about 300 and about 1200 m/sec, which is relatively slower. This is because a flow velocity of the heated powder is relatively more rapid than that of the unheated powder. Thus, even though the spraying velocity of powder is relatively lower, the powder heated to the predetermined temperature range enables realization of the desired velocity at the instant when powder particles collide with the substrate. Also, if the powder is heated to the predetermined temperature range, its powder particles are apt to be transformed when the powder particles collide with the substrate, thereby resulting in high efficiency of powder deposition on the substrate.

In addition, a filter (not shown) may be provided in the pipe 600 between the spraying nozzle 400 and the powder supplier 700, so as to filter out the particles having a size above a predetermined value by floating the powder on the gas.

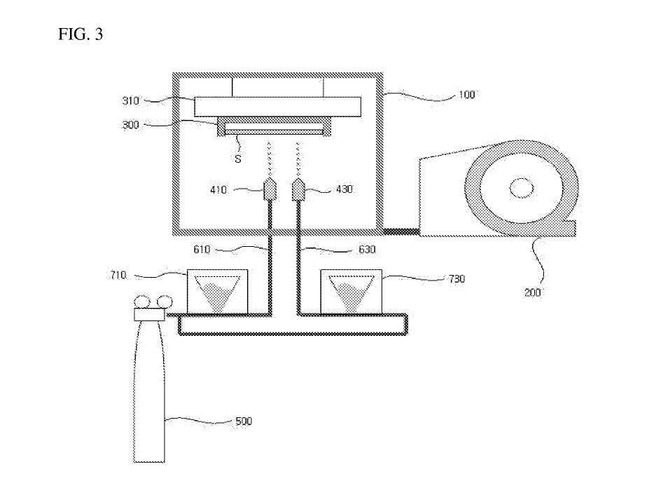

FIG. 3 is a diagram schematically illustrating a powder coating apparatus according to another embodiment of the present invention. Except a modification in a powder supplier, a pipe and a spraying nozzle, the powder coating apparatus of FIG. 3 is identical in structure to that of FIG. 2. Accordingly, the same reference numbers will be used throughout the drawings to refer to the same or like parts, and the detailed explanation for the same parts will be omitted.

As shown in FIG. 3, the powder coating apparatus according to another embodiment of the present invention includes a first powder supplier 710 to supply a first powder; a second powder supplier 730 to supply a second powder; a first pipe 610 coupled with the first powder supplier 710; a second pipe 630 coupled with the second powder supplier 730; a first spraying nozzle 410 coupled with the first pipe 610; and a second spraying nozzle 430 coupled with the second pipe 630.

According as the first spraying nozzle 410 and the second spraying nozzle 430 respectively spray the first powder and the second powder at the same time, both the first powder and the second powder are coated on the substrate (S). In another aspect, spraying of the second powder through the second spraying nozzle 430 may follow spraying of the first powder through the first spraying nozzle 410, that is, the first powder and the second powder may be alternately sprayed on the substrate (S). As a result, the different kinds of powder materials may be deposited on the substrate in sequence, and the various kinds of powder materials may be coated in various patterns.

In FIG. 3, the first spraying nozzle 410 and the second spraying nozzle 430 are arranged perpendicular to the plane of substrate (S). Alternatively, the first spraying nozzle 410 and the second spraying nozzle 430 may be tilted with respect to the plane of substrate (S), in the same mode of FIG. 2.

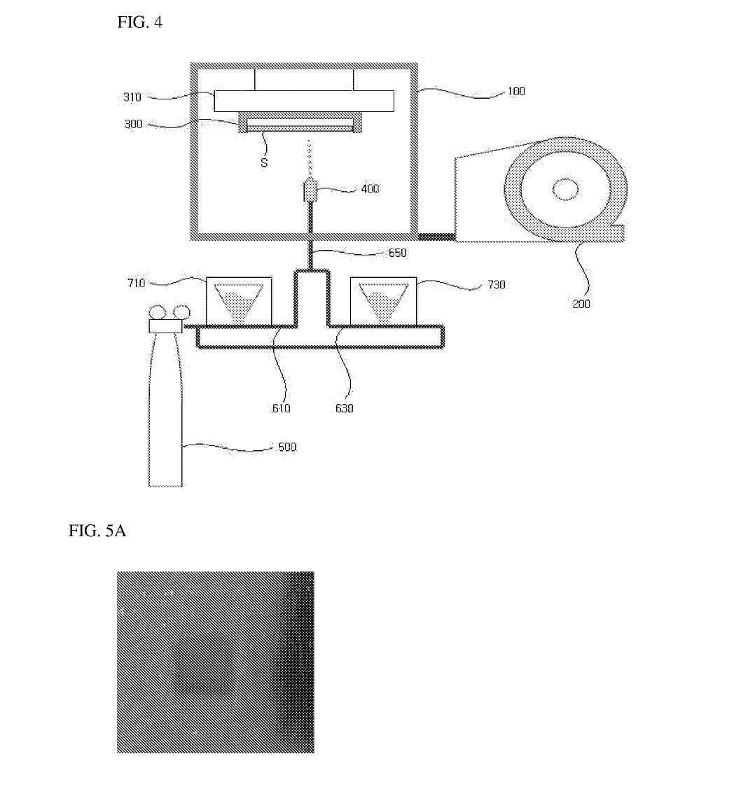

FIG. 4 is a diagram schematically illustrating a powder coating apparatus according to another embodiment of the present invention. Except a modification in a powder supplier, a pipe and a spraying nozzle, the powder coating apparatus of FIG. 4 is identical in structure to that of FIG. 2. Accordingly, the same reference numbers will be used throughout the drawings to refer to the same or like parts, and the detailed explanation for the same parts will be omitted.

As shown in FIG. 4, the powder coating apparatus according to another embodiment of the present invention includes a first powder supplier 710 to supply a first powder; a second powder supplier 730 to supply a second powder; a first pipe 610 coupled with the first powder supplier 710; a second pipe 630 coupled with the second powder supplier 730; a third pipe 650 into which the first and second pipes 610 and 630 are integrated; and one spraying nozzle 400 coupled with the third pipe 650.

Accordingly, a powder mixture with a desired content ratio can be obtained by selectively changing a content of the first powder from the first powder supplier 710 and a content of the second powder from the second powder supplier 730, and can be coated on the substrate (S) with easiness. Especially, if the first powder from the first powder supplier 710 and the second powder from the second powder supplier 730 are consecutively changed in their supply amounts, a content ratio of the first powder to the second powder may be consecutively changed in the mixture powder to be coated on the substrate (S).

In FIG. 4, the spraying nozzle is arranged perpendicular to the plane of substrate (S). Alternatively, the spraying nozzle may be tilted with respect to the plane of substrate (S), in the same mode of FIG. 2.

### Powder Coating Method

Hereinafter, a powder coating method according to the present invention will be described with reference to the powder coating apparatus of FIG. 2 to FIG. 4. The powder coating method according to the present invention is not limited to the use of powder coating apparatus shown in FIG. 2 to FIG. 4.

First, a predetermined powder is prepared, which is made of metal or ceramic powder, of which the grain size is about 0.1 to about 10 μm. The powder may be supplied from the powder supplier 700 to the pipe 600 as shown in FIG. 2. As shown in FIGS. 3 and 4, the first powder may be supplied from the first powder supplier 710 to the first pipe 610, and the second powder may be supplied from the second powder supplier 730 to the second pipe 620. The first powder may be different from the second powder in material and supply amount.

Next, the gas injection is performed at the room temperature so that the injected gas carries the powder to the predetermined spraying nozzle. For example, the gas is supplied to the pipe 600 by the gas supplier 500, as shown in FIG. 2 to FIG. 4. In this case, an injection pressure of the gas is controlled in consideration to the velocity of powder sprayed through the spraying nozzle.

The powder may be carried by the supplied gas in one course or two courses or more. That is, as shown in FIG. 2, the powder may be carried to the spraying nozzle 400 through the use of gas flowing in the pipe 600. As shown in FIG. 3, the first powder may be carried to the first spraying nozzle 410 through the use of gas flowing in the first pipe 610, and the second powder may be carried to the second spraying nozzle 430 through the use of gas flowing in the second pipe 630. As shown in FIG. 4, after the first powder and the second powder may be respectively carried through the use of gas flowing in the first pipe 610 and second pipe 630, the mixture of first powder and second powder may be carried to the spraying nozzle 400 through the use of gas flowing in the third pipe 650 into which the first and second pipes 610 and 630 are integrated.

For carrying the powder by the gas flow, the powder may be heated to the predetermined temperature between the room temperature and about 300° C. In this case, the velocity of powder sprayed through the spraying nozzle is set relatively slower, for example, about 300 to about 1200 m/sec. Through the floating of powder on the gas, the powder particles having the size above the predetermined value may be filtered out.

Then, the powder carried under conditions of room temperature and vacuum state is sprayed on the predetermined substrate through spraying nozzle.

As shown in FIG. 2 to FIG. 4, these steps are performed inside the chamber 100 under the vacuum state through the use of vacuum pump 200. The powder is sprayed at a velocity of about 500 to about 1200 m/sec through the spraying nozzle 400, and more preferably, about 600 to about 1200 m/sec. The substrate may be made of metal, ceramic or polymer.

As mentioned above, a slant spraying angle of powder with respect to the plane of substrate is advantageous to the control of spraying velocity of powder. With the spray of powder on the substrate, the substrate is moved at the same time, so that the powder is coated in the predetermined pattern on the substrate.

The powder may be sprayed on the substrate (S) through the use of one spraying nozzle 400 as shown in FIG. 2. Also, as shown in FIG. 3, the first powder may be sprayed on the substrate (S) through the first spraying nozzle 410, and the second powder may be sprayed on the substrate (S) through the second spraying nozzle 430, as shown in FIG. 3. As shown in FIG. 4, the mixture of first powder and second powder may be sprayed on the substrate (S) through one spraying nozzle 400.

In FIG. 3, the first powder and the second powder may be simultaneously or alternately sprayed on the substrate (S).

### EXPERIMENTAL EXAMPLE

The metal substrates made of stainless steel, copper, or aluminum alloy are prepared, and the polymer substrates made of polyethylene terephthalate (PET) and polymethyl methacrylate (PMMA) are prepared. Also, the ceramic powder made of TiO₂ having a grain size less than about 5 μm (Sigma-Aldrich, St. Louis, Mo., USA) and Sn having a grain size less than about 5 μm (Sigma-Aldrich, St. Louis, Mo., USA) is prepared.

Under the conditions set as the following table 1, the ceramic powder or the metal power is deposited on 5×5 mm² area of the substrate through the spray of compressed air.

TABLE 1

| Parameters | Values |
|---|---|
| Gas pressure(MPa) | 0.7 |
| Nozzle throat diameter(μm) | 590 |
| Spraying velocity(m/sec) | 600~800 |
| Chamber pressure(MPa) | 0.02~0.04 |
| Chamber temperature(° C.) | 15° C. |
| Gas flow(L/min) | 6~12 |
| Distance between substrate and nozzle(mm) | 1.5 |

At this time, the deposition results can be checked by optical images or scanning electron microscope (SEM) images, and the chemical composition of coating layer can be checked by an analysis of energy dispersive X-ray (EDX) or X-ray photoelectron spectroscopy (XPS).

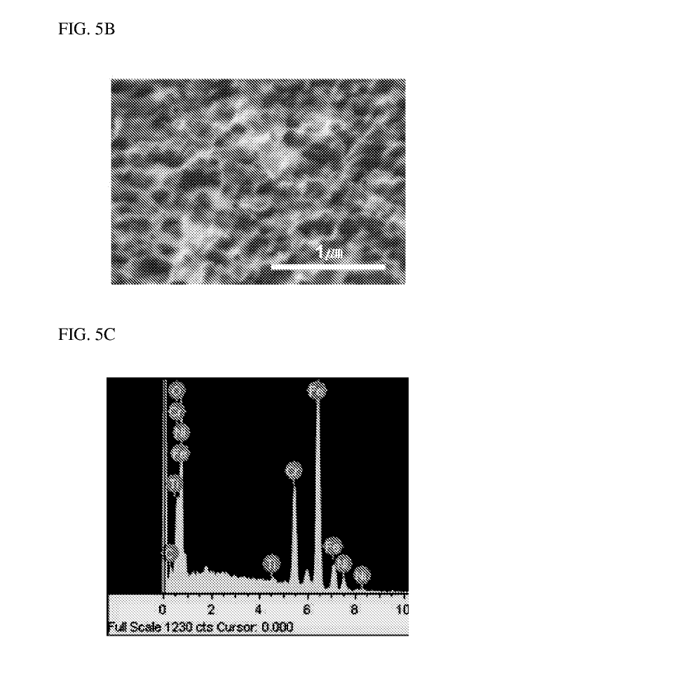

FIG. 5A shows optical images when TiO₂ powder is coated on the stainless steel substrate. FIG. 5B shows SEM images when TiO₂ powder is coated on the stainless steel substrate. FIG. 5C shows EDX analysis graph when TiO₂ powder is coated on the stainless steel substrate. As shown in FIG. 5A, TiO₂ powder is stably and smoothly coated on the stainless steel substrate. As shown in FIG. 5B, the grain size of TiO₂ powder coated is less than 1 μm, which is smaller than the grain size of powder before being coated. This is because the powder particles are deformed and deposited on the stainless steel substrate during their collision against the stainless steel substrate. Also, as shown in FIG. 5C, the coating layer comprises compositions of the stainless steel substrate and Ti material, wherein TiO₂ powder is stably combined with and completely coated on the stainless steel substrate.

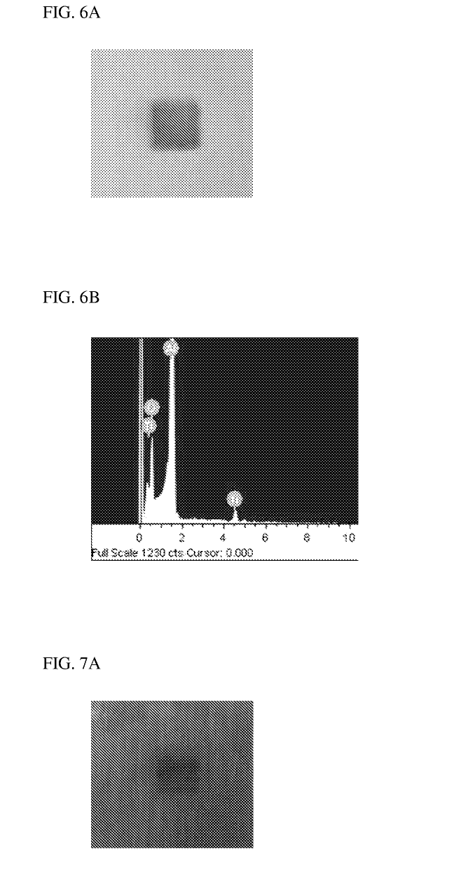

FIG. 6A shows optical images when TiO₂ powder is coated on the aluminum alloy substrate. FIG. 6 shows EDX analysis graph when TiO₂ powder is coated on the aluminum alloy substrate. As shown in FIG. 6A, TiO₂ powder is stably and smoothly coated on the aluminum alloy substrate. As shown in FIG. 6B, the coating layer comprises Ti materials and compositions of the aluminum alloy substrate, wherein TiO₂ powder is stably combined with and completely coated on the aluminum alloy substrate.

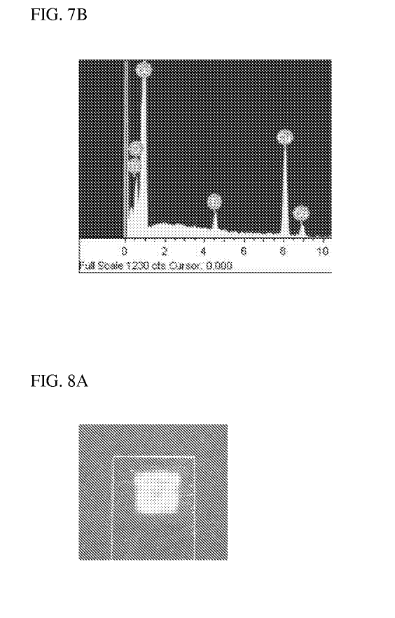

FIG. 7A shows optical images when TiO₂ powder is coated on the copper alloy substrate. FIG. 7B shows EDX analysis graph when TiO₂ powder is coated on the copper alloy substrate. As shown in FIG. 7A, TiO₂ powder is stably and smoothly coated on the copper alloy substrate. As shown in FIG. 7B, the coating layer comprises Ti materials and compositions of the copper alloy substrate, wherein TiO₂ powder is stably combined with and completely coated on the copper alloy substrate.

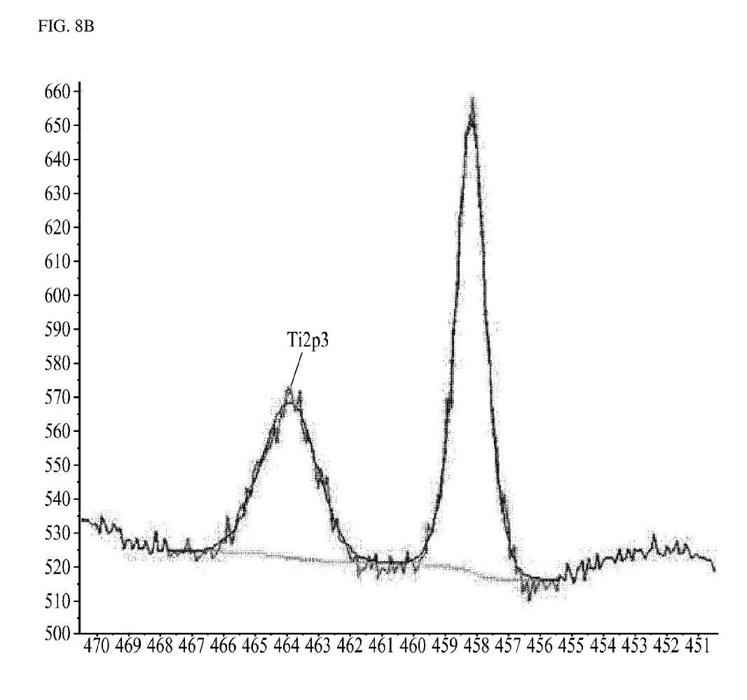

FIG. 8A shows optical images when TiO₂ powder is coated on the PET substrate. FIG. 8B shows XPS analysis graph when TiO₂ powder is coated on the PET substrate. As shown in FIG. 8A, TiO₂ powder is stably and smoothly coated on the PET substrate. In FIG. 8B, the PET substrate smoothly coated with TiO₂ powder can be confirmed by the appearance of Ti peak.

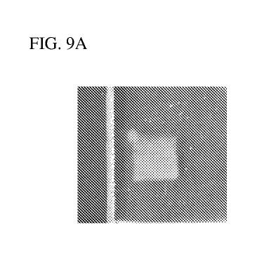

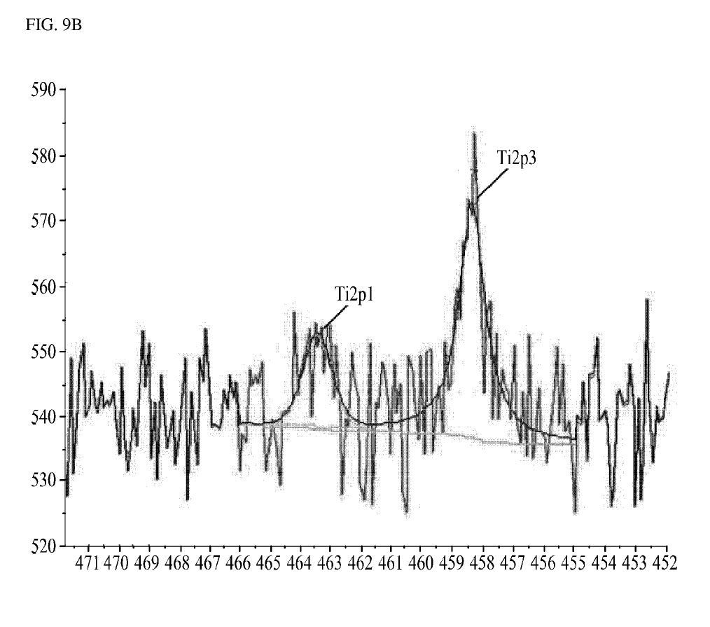

FIG. 9A shows optical images when TiO₂ powder is coated on the PMMA substrate. FIG. 9B shows XPS analysis graph when TiO₂ powder is coated on the PMMA substrate. As shown in FIG. 9A, TiO₂ powder is stably and smoothly coated on the PMMA substrate. In FIG. 9B, the PMMA substrate smoothly coated with TiO₂ powder can be confirmed by the appearance of Ti peak.

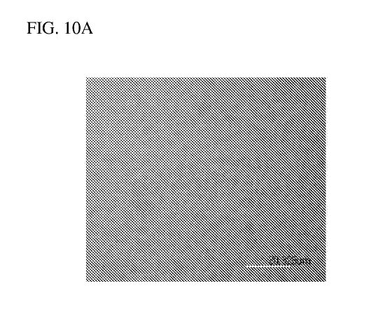

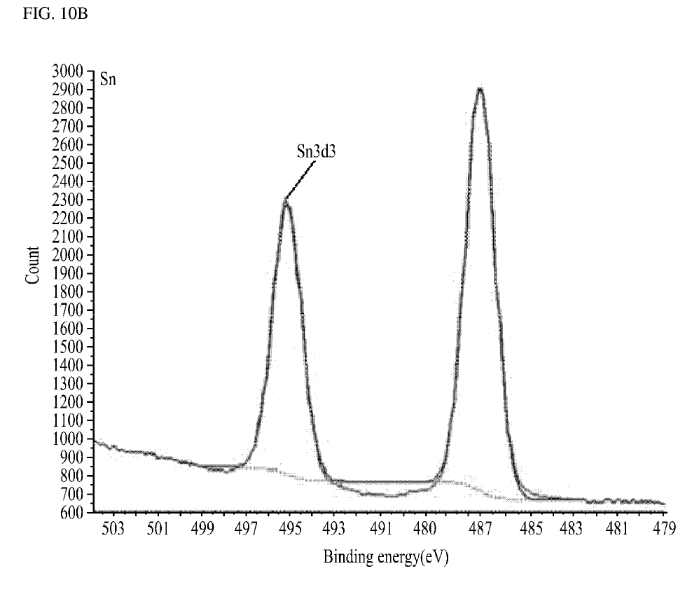

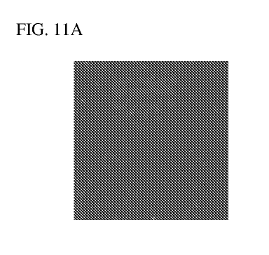

FIG. 10A shows optical images when Sn powder is coated on the stainless steel substrate. FIG. 10B shows XPS analysis graph when Sn powder is coated on the stainless steel substrate. As shown in FIG. 10A, Sn powder is stably and smoothly coated on the stainless steel substrate. In FIG. 10B, the stainless steel substrate smoothly coated with Sn powder can be confirmed by the appearance of Sn peak.

### COMPARATIVE EXAMPLE

The metal substrate made of stainless steel is prepared, and the ceramic powder made of TiO₂ powder having a grain size less than 5 μm (Sigma-Aldrich, St. Louis, Mo., USA) is prepared. Except that a powder-spraying velocity of 340 m/sec is set through the use of a subsonic nozzle (having an inlet of 10 mm×0.4 mm) instead of the supersonic nozzle, a coating process for the comparative example is performed under the same conditions as those shown in the table 1 of the aforementioned experimental example.

At this time, the deposition results can be checked by optical images, and the chemical composition of coating layer can be checked by an analysis of energy dispersive X-ray (EDX).

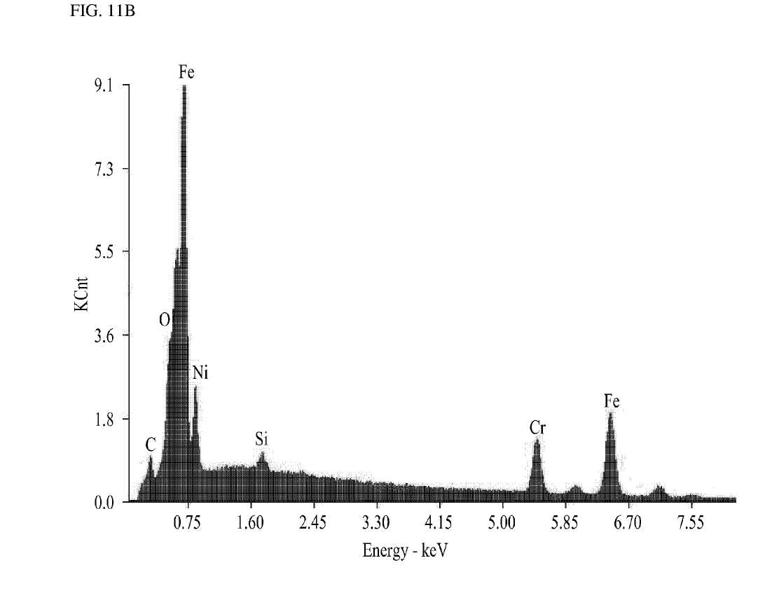

FIG. 11A shows optical images, and FIG. 11B shows EDX analysis graph. From the observation of FIG. 11A, it is difficult to clearly confirm that TiO2 powder is coated on the substrate. However, FIG. 11B definitely shows that the coating layer has no Ti material, that is, TiO₂ powder is not coated on the substrate.

When introducing elements or features and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of coating powder on a substrate comprising:
supplying a predetermined powder;
carrying the supplied powder to a predetermined spraying nozzle by injecting a gas at a room temperature; and
spraying the powder carried under conditions of the room temperature and vacuum state on the substrate through the spraying nozzle,
wherein the grain size of the predetermined powder is in a range between about 0.1 to about 10 μm, and the powder is sprayed on the substrate at a velocity of about 500 to about 1200 m/sec.

2. The method according to claim 1, wherein the predetermined powder is made of metal or ceramic, and the substrate is made of metal, ceramic or polymer.

3. The method according to claim 1, further comprising:
heating the carried powder to a predetermined temperature between the room temperature and about 300° C., wherein the powder is sprayed on the substrate at a velocity of about 300 to about 1200 m/sec.

4. The method according to claim 1, further comprising:
filtering out the powder particles having a diameter size above a predetermined value through the floating of powder on the gas.

5. The method according to claim 1, wherein the powder is sprayed at a tilt angle with respect to the plane of substrate.

6. The method according to claim 1, further comprising:
moving the substrate during spraying the power on the substrate, so as to coat the powder in a predetermined pattern on the substrate.

7. The method according to claim 1, wherein:
supplying the powder comprises supplying a first powder and supplying a second powder;
carrying the powder comprises carrying the first powder in a first course, and carrying the second powder in a second course; and
spraying the powder on the substrate comprises spraying the first powder carried in the first course on the substrate through a first spraying nozzle, and spraying the second powder carried in the second course on the substrate through a second spraying nozzle,
wherein spraying the first powder through the first spraying nozzle and spraying the second powder through the second spraying nozzle are performed simultaneously or alternatively.

8. The method according to claim 1, wherein:
supplying the powder comprises supplying a first powder and supplying a second powder;
carrying the powder comprises carrying the first powder in a first course, and carrying the second powder in a second course; and
spraying the powder on the substrate comprises spraying the mixture of first powder and second powder on the substrate through one spraying nozzle,
wherein the first powder and the second powder are consecutively changed in their supply amounts, so as to make a content ratio of the first powder to the second powder changed consecutively in the mixture thereof.

9. A powder coating apparatus comprising:
a chamber;
a vacuum pump, coupled with the chamber, for making the chamber of a vacuum state;
a substrate supporter, disposed inside the chamber, for supporting a predetermined substrate;
a spraying nozzle, disposed inside the chamber, for spraying a predetermined powder on the substrate;
a gas supplier, disposed outside the chamber, for supplying a predetermined gas;
a pipe, having one end coupled with the gas supplier and the other end coupled with the spraying nozzle, for guiding the gas supplied from the gas supplier to the spraying nozzle; and
a powder supplier, coupled with the pipe, for supplying the predetermined powder to the pipe through which the gas flows.

10. The powder coating apparatus according to claim 9, wherein the spraying nozzle comprises a first opening coupled with the pipe, a second opening to spray the powder on the substrate, and a nozzle throat having a diameter of about 100 μm to about 3 mm between the first opening and the second opening, wherein the diameter of nozzle throat becomes gradually smaller in a direction from the first opening toward the nozzle throat, and becomes gradually larger in a direction from the nozzle throat toward the second opening, so as to spray the powder through the spraying nozzle at a velocity of about 500 to about 1200 m/sec.

11. The powder coating apparatus according to claim 9, further comprising a heater, disposed between the spraying nozzle and the powder supplier, for heating the carried powder to a predetermined temperature between a room temperature and about 300° C.

12. The powder coating apparatus according to claim 9, further comprising a filter, disposed in the pipe between the spraying nozzle and the powder supplier, for filtering out the particles having a size above a predetermined value through the floating of powder on the gas.

13. The powder coating apparatus according to claim 9, wherein the spraying nozzle is tilted with respect to the plane of substrate.

14. The powder coating apparatus according to claim 9, wherein the substrate supporter is movable along the X-axis and Y-axis.

15. The powder coating apparatus according to claim 9, wherein:
the powder supplier comprises a first powder supplier to supply a first powder and a second powder supplier to supply a second powder;
the pipe comprises a first pipe coupled with the first powder supplier, and a second pipe coupled with the second powder supplier; and
the spraying nozzle comprises a first spraying nozzle coupled with the first pipe, and a second spraying nozzle coupled with the second pipe.

16. The powder coating apparatus according to claim 9, wherein:
the powder supplier comprises a first powder supplier to supply the first powder, and a second powder supplier to supply the second powder; and
the pipe comprises a first pipe coupled with the first powder supplier, a second pipe coupled with the second powder supplier, and a third pipe into which the first and second pipes are integrated,
wherein the spraying nozzle is coupled with the third pipe.
